(19) United States
(12) Patent Application Publication
(10) Pub. No.: US 2026/0130502 A1
(43) Pub. Date: May 14, 2026

(54) TELESCOPIC RACK

(71) Applicant: Gyrobot Technology (Suzhou) Co., Ltd., Suzhou (CN)

(72) Inventors: Weifeng XU, Suzhou (CN); Daoxing WANG, Suzhou (CN); SENG THOR ANG, Suzhou (CN)

(73) Assignee: Gyrobot Technology (Suzhou) Co., Ltd., Suzhou (CN)

(21) Appl. No.: 19/383,141

(22) Filed: Nov. 7, 2025

(30) Foreign Application Priority Data
Nov. 13, 2024 (CN) 202411618178.2

(51) Int. Cl. A47B 46/00; A47B 81/00; H01L 21/677

(52) U.S. Cl. CPC A47B 46/00; A47B 81/00; H10P 72/3404

(57) ABSTRACT

An embodiment of the present disclosure discloses a telescopic rack, and the present disclosure relates to the technical field of warehousing devices. The telescopic rack includes a rack body, material trays, and driving mechanisms. The rack body includes a shielding layer and a storage layer located below the shielding layer, the storage layer is provided with sliding rails extending in a first direction, the material tray is slidably mounted on the sliding rail through a sliding block, the material tray is provided with at least one storage position for holding goods, and the driving mechanism is configured to drive the material tray to move along the sliding rail so that the storage position moves out of the storage layer.

The present application claims priority to Chinese Patent Application No. 202411618178.2, filed on November 13, 2024. The disclosure of the above-referenced application is hereby incorporated by reference in its entirety.

### BACKGROUND

In the fields of warehousing and logistics, a telescopic rack is a common storage device. The storage layers of the conventional telescopic rack are fixed, typically with a fixed-dimension layer height, and the storage layers cannot be adjusted based on actual needs. In actual use, due to the dimensions of goods, different angles at which clamping jaws clamp the goods, or the like, the layer height may prevent the goods from being smoothly transferred onto the storage layer.

Therefore, a telescopic rack capable of being telescopically adjusted based on actual situations is required to improve the adaptability of the telescopic rack and the utilization rate of the storage space.

### SUMMARY

The present disclosure aims to solve at least one of the technical problems in some embodiments. Therefore, the present disclosure provides a telescopic rack to solve the problem in some embodiments that the layer height of a storage layer affects the smooth transfer of goods onto the storage layer.

The present disclosure relates to the technical field of warehousing devices, and in particular, to a telescopic rack.

The objective of the present disclosure can be achieved by the following technical solutions.

The present disclosure provides a telescopic rack. The telescopic rack includes a rack body, material trays, and driving mechanisms. The rack body includes a shielding layer and a storage layer located below the shielding layer, the storage layer is provided with sliding rails extending in a first direction, the material tray is slidably mounted on the sliding rail through a sliding block, the material tray is provided with at least one storage position for holding goods, and the driving mechanism is configured to drive the material tray to move along the sliding rail so that the storage position moves out of the storage layer.

Optionally, the storage layer is provided with a plurality of material trays spaced apart in a second direction, the second direction being perpendicular to the first direction.

Optionally, at least one storage position bottom plate is mounted on the material tray, and the storage position is located on the storage position bottom plate and is in a one-to-one correspondence with the storage position bottom plate.

Optionally, the storage position includes a first storage position for holding a wafer cassette and a second storage position for holding a wafer tray carrier; a plurality of first stop blocks defining the first storage position in an enclosing manner and a plurality of second stop blocks defining the second storage position in an enclosing manner are mounted on the storage position bottom plate, the second stop block is disposed on an outer side of the first stop block, and the second stop block at least partially extends above the first stop block.

Optionally, the first stop block includes a first support portion and a first side stop portion disposed at an edge of a top surface of the first support portion, the first side stop portion defines the first storage position on an inner side of the first support portion in an enclosing manner, and the first support portion is configured to support the wafer cassette in the first storage position; the second stop block includes a second support portion and a second side stop portion disposed at an edge of a top surface of the second support portion, the second side stop portion defines the second storage position on an inner side of the second support portion in an enclosing manner, and the second support portion is configured to support the wafer tray carrier in the second storage position; a height of the second support portion on the storage position bottom plate is not lower than a height of the first side stop portion on the storage position bottom plate.

Optionally, the telescopic rack further includes two first in-position sensors and two second in-position sensors; the two first in-position sensors are disposed in the first support portions of two first stop blocks along a diagonal of the first storage position, respectively, and the two second in-position sensors are disposed in the second support portions of two second stop blocks along a diagonal of the second storage position, respectively.

Optionally, a presence sensor is separately disposed below each storage position bottom plate, and the presence sensor is configured to detect whether goods are placed on a corresponding storage position bottom plate.

Optionally, the telescopic rack further includes a display screen for displaying information about goods on the telescopic rack; the display screen is mounted on the rack body with an adjustable inclination angle.

Optionally, the telescopic rack further includes barcode readers in a one-to-one correspondence with the storage positions; the barcode reader is configured to read barcode information on goods.

Optionally, a plurality of feet are mounted at a bottom of the rack body;

and/or,

### a ground wire in contact with ground is mounted at the bottom of the rack body

Beneficial effects: According to the present disclosure, through the arrangement of the material tray in a sliding manner on the storage layer, when goods are placed into or taken from the storage position of the material tray, the material tray can slide toward the outer side of the storage layer along the sliding rail in advance, so that the storage position slides out of the storage layer, thereby preventing an operator or handling apparatus (such as clamping jaw) from being affected by the layer height of the storage layer when loading or unloading goods in the storage position, and improving the adaptability of the telescopic rack and the utilization rate of the storage space.

### BRIEF DESCRIPTION OF DRAWINGS

The present disclosure is further described below with reference to the accompanying drawings.

FIG. 1 is a perspective view of a telescopic rack according to an embodiment of the present disclosure;

FIG. 2 is a side view of a telescopic rack according to an embodiment of the present disclosure; and

FIG. 3 is a schematic structural view of a storage position bottom plate and structures on the storage position bottom plate according to an embodiment of the present disclosure.

### Description of reference numerals:

10. rack body; 11. material tray; 12. driving mechanism; 13. sliding rail; 131. sliding block; 14. shielding layer; 15. storage layer; 16. storage position bottom plate; 17. first stop block; 171. first support portion; 172. first side stop portion; 173. first guiding portion; 18. second stop block; 181. second support portion; 182. second side stop portion; 183. second guiding portion; 19. first in-position sensor; 20. second in-position sensor; 21. limiting rod; 22. third guiding portion; 23. second clearance hole; 24. display screen; 25. bracket; 26. connecting member; 27. mounting circular hole; 28. arc-shaped adjustment waist hole; 29. barcode reader; 30. universal wheel; 31. foot; 32. ground wire; 33.presence sensor; 4. storage position; 41. first storage position; 42. second storage position; 5. wafer cassette; 6. wafer tray carrier.

### DETAILED DESCRIPTION OF THE EMBODIMENTS

The technical solutions in embodiments of the present disclosure will be clearly and fully described hereinafter with reference to the accompanying drawings in the embodiments of the present disclosure, and it is apparent that the described embodiments are only a portion, but not all of the embodiments of the present disclosure. Based on the embodiments in the present disclosure, all other embodiments obtained by those of ordinary skill in the art without creative work shall fall within the protection scope of the present disclosure.

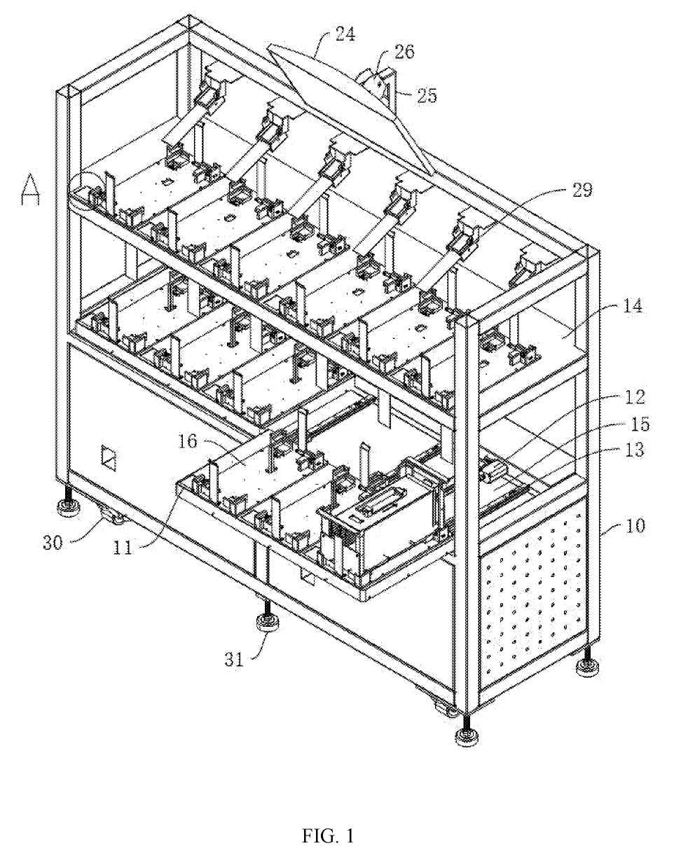

Referring to FIGS. 1 to 3, in some embodiments, the present disclosure provides a telescopic rack. The telescopic rack includes a rack body 10, material trays 11, and driving mechanisms 12. The rack body 10 includes a shielding layer 14 and a storage layer 15 located below the shielding layer 14, the storage layer 15 is provided with sliding rails 13 extending in a first direction, the first direction is the width direction of the storage layer 15, the material tray 11 is slidably mounted on the sliding rail 13 through a sliding block 131, the material tray 11 is provided with at least one storage position 4 for holding goods, and the driving mechanism 12 is configured to drive the material tray 11 to move along the sliding rail 13 so that the storage position 4 moves out of the storage layer 15.

According to the present disclosure, it is intended that through the arrangement of the material tray 11 in a sliding manner on the storage layer 15, when goods are placed into or taken from the storage position 4 of the material tray 11, the material tray 11 can slide toward the outer side of the storage layer 15 along the sliding rail 13 in advance, so that the storage position 4 slides out of the storage layer 15, thereby preventing an operator or handling apparatus (such as clamping jaw) from being affected by the layer height of the storage layer 15 when loading or unloading goods in the storage position 4, and improving the adaptability of the telescopic rack and the utilization rate of the storage space.

It should be noted that the shielding layer 14 in the present disclosure is located at the top of the telescopic rack, and the shielding layer 14 may be a top cover structure only configured for shielding, or may be a layered plate structure or a frame structure configured for holding goods. When the shielding layer 14 is a layered plate structure or a frame structure capable of holding goods, the material tray 11 can also be mounted on the shielding layer 14, but since there is no shielding on the shielding layer 14, the material tray 11 may be fixedly mounted on the shielding layer 14. The storage layer 15 may be a layered plate structure or a frame structure, the storage layer 15 is located directly below the shielding layer 14, and one or more storage layers 15 may be provided, which is not specifically limited herein. The layer height of the storage layer 15 refers to a spacing between adjacent storage layers 15 or a spacing between the storage layer 15 and an adjacent shielding layer 14.

In some embodiments, the storage layer 15 is provided with a plurality of material trays 11 spaced apart in a second direction; the second direction is perpendicular to the first direction, and the second direction is the length direction of the storage layer 15. The number of material trays 11 can be adaptively set according to the specific length of the storage layer 15, as long as the material trays 11 can move stably relative to the storage layer 15.

The driving mechanisms 12 are disposed in a one-to-one correspondence with the material trays 11, and the driving mechanisms 12 may be air cylinders.

The number of sliding rails 13 corresponding to each material tray 11 can be adaptively set according to the length of the material tray 11, as long as the material tray 11 can move smoothly.

In some embodiments, at least one storage position bottom plate 16 is mounted on the material tray 11, and the storage position bottom plate 16 is provided with one storage position.

Specifically, each material tray 11 may be provided with three storage position bottom plates 16 separately, so that each material tray 11 is provided with three storage positions. The driving mechanism 12 may drive the corresponding material tray 11 to move the three storage positions on the material tray 11 out of the storage layer 15 synchronously.

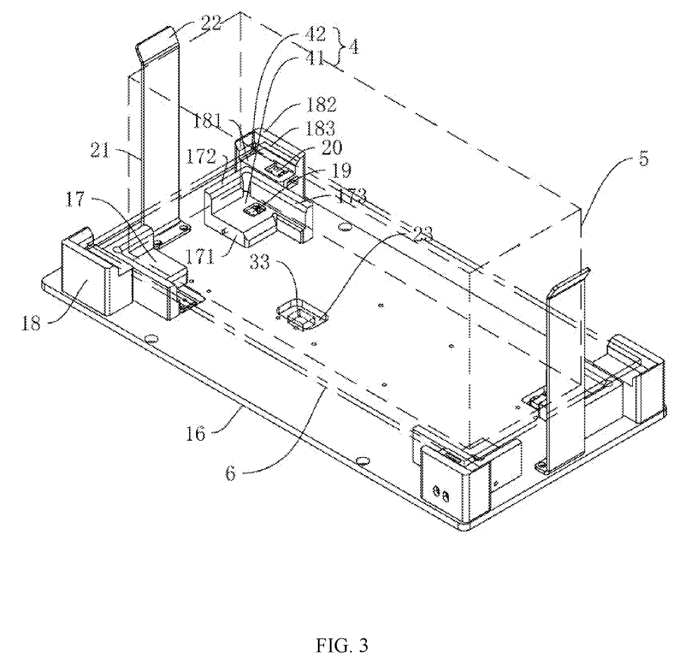

Referring to FIG. 3, in order to improve the adaptability of each storage position, goods of different dimensions can be placed in each storage position. Specifically, each storage position includes a first storage position 41 for holding a wafer cassette and a second storage position 42 for holding a wafer tray carrier, and the first storage position 41 is located inside the second storage position 42. The first storage position 41 is enclosed by a plurality of first stop blocks 17 mounted on the storage position bottom plate 16, and the second storage position 42 is enclosed by a plurality of second stop blocks 18 mounted on the storage position bottom plate 16; the plurality of second stop blocks 18 are disposed around the plurality of first stop blocks 17, and the second stop blocks 18 at least partially extend above the first stop blocks 17, so as to prevent the first stop blocks 17 from affecting the enclosure of the second stop blocks 18.

When the storage position bottom plate 16 is configured to hold the wafer cassette, the wafer cassette may be placed in the first storage position 41 enclosed by first stop plates, and the plurality of first stop plates are disposed around the periphery of the wafer cassette 5 to limit the wafer cassette 5, so as to prevent the wafer cassette 5 from shaking relative to the telescopic rack during the movement of the telescopic rack.

When the storage position bottom plate 16 is configured to hold the wafer tray carrier 6, the wafer tray carrier 6 may be placed in the second storage position 42 enclosed by second stop plates. In this case, the wafer tray carrier 6 is located above the first stop block 17 and is supported by a plurality of first stop blocks 17 together or supported by a plurality of second stop plates together, and the periphery of the wafer tray carrier 6 is stopped by the plurality of second stop plates, so as to prevent the wafer tray carrier 6 from shaking relative to the telescopic rack during the movement of the telescopic rack.

In some embodiments, four first stop blocks 17 are provided and are disposed proximal to four corners of the storage position bottom plate 16, respectively. Each first stop block 17 includes a first support portion 171 and a first side stop portion 172 disposed at the edge of the top surface of the first support portion 171. Both the first support portion 171 and the first side stop portion 172 are substantially in an L shape, and one side of the first support portion 171 extends toward the inner side of the first side stop portion 172, so that a first in-position sensor 19 is subsequently mounted in the first support portion 171. The first side stop portion 172 defines the first storage position on the inner side of the first support portion 171 in an enclosing manner.

When the wafer cassette 5 is placed in the first storage position 41, the first support portion 171 supports the wafer cassette 5, and the first side stop portion 172 stops the wafer cassette 5 from the periphery of the wafer cassette 5, so that the wafer cassette 5 can be stably limited on the corresponding storage position bottom plate 16.

Four second stop blocks 18 are also provided; the four second stop blocks are disposed proximal to four corners of the storage position bottom plate 16, respectively, and located on the opposite outer sides of the four first stop blocks 17. The second stop block 18 includes a second support portion 181 and a second side stop portion 182; the second support portion 181 is substantially in the shape of a rectangular block, the second side stop portion 182 is substantially in an L shape, and the second side stop portion 182 is disposed at the edge of the top surface of the second support portion 181, so that a second in-position sensor 20 for detecting whether the wafer tray carrier is correctly placed in the second storage position is subsequently mounted in the second support portion 181 and on the inner side of the second side stop portion 182. The height of the second support portion 181 on the storage position bottom plate 16 is not lower than the height of the first side stop portion 172 on the storage position bottom plate 16.

When the wafer tray carrier 6 is placed in the second storage position 42, the second support portion 181 supports the wafer tray carrier 6, and the second side stop portion 182 stops the wafer tray carrier 6 from the periphery of the wafer tray carrier 6, so that the wafer tray carrier 6 can be stably limited on the corresponding storage position bottom plate 16.

In some embodiments, the first side stop portion 172 is provided with a first guiding portion 173, and the first guiding portion 173 is inclined downward from the top of the first side stop portion 172 to guide the wafer cassette 5 to fall in the first storage position 41.

The second side stop portion 182 is provided with a second guiding portion 183, and the second guiding portion 183 is inclined downward from the top of the second side stop portion 182 to guide the wafer tray carrier 6 to fall in the second storage position 42.

In some embodiments, a limiting rod 21 is fixedly mounted at each end of two ends of each storage position bottom plate 16 for stopping goods after the goods move away from the stop of the first stop block 17 or the second stop block 18, so as to prevent the goods from falling out of the storage position bottom plate 16.

Further, the top of each limiting rod 21 is provided with a third guiding portion 22, and the third guiding portion 22 is inclined downward from the top of the limiting rod 21 to guide the goods to fall on the corresponding storage position bottom plate 16.

The telescopic rack further includes two first in-position sensors 19 and two second in-position sensors 20. The two first in-position sensors 19 are disposed in the first support portions 171 of the two first stop blocks 17 along the diagonal of the first storage position, respectively, and the two second in-position sensors 20 are disposed in the second support portions 181 of the two second stop blocks 18 along the diagonal of the second storage position, respectively. First clearance holes corresponding to the first in-position sensor 19 and the second in-position sensor 20 are formed in the top surfaces of the first support portion 171 and the second support portion 181, respectively, so as to allow the detection signals of the first in-position sensor 19 and the second in-position sensor 20 to pass through.

When the goods are placed in the first storage position 41 on the storage position bottom plate 16, the goods may be detected by the two first in-position sensors 19 simultaneously to determine that the goods are accurately placed in the first storage position. When the goods are placed in the second storage position 42 on the storage position bottom plate 16, the goods may be detected by the two second in-position sensors 20 simultaneously to determine that the goods are accurately placed in the second storage position 42. This ensures that the goods are stably placed on the storage position bottom plate 16.

A presence sensor 33 is separately disposed below each storage position bottom plate 16, and the presence sensor 33 can detect whether goods are placed on the corresponding storage position bottom plate 16. The presence sensor 33 may be fixedly mounted at the bottom of the material tray 11 and is disposed in a hidden manner. The material tray 11 and the storage position bottom plate 16 are provided with a second clearance hole 23 corresponding to the presence sensor 33, so as to provide clearance for the detection signal transmitted by the presence sensor 33.

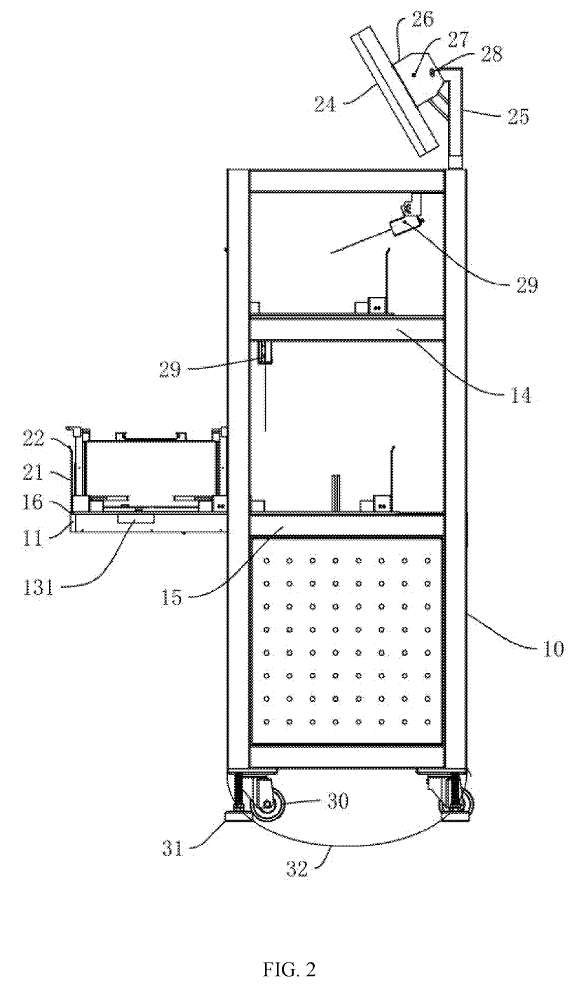

Referring to FIGS. 1 and 2, the telescopic rack further includes a display screen 24 for displaying the information about goods on the telescopic rack, and the display screen 24 is mounted on the rack body 10 with an adjustable inclination angle.

Specifically, a bracket 25 is fixedly mounted on the top of the rack body 10, and a connecting member 26 assembled with the bracket 25 is fixedly mounted on the back surface of the display screen 24. The connecting member 26 is provided with a mounting circular hole 27 and an arc-shaped adjustment waist hole 28 spaced apart in the horizontal direction, the mounting circular hole 27 is relatively proximal to the display screen 24, and the radian of the arc-shaped adjustment waist hole 28 is set along the adjustment track of the display screen 24. The connecting member 26 and the bracket 25 are adjustably and fixedly connected by a first bolt passing through the mounting circular hole 27 and a second bolt passing through the arc-shaped adjustment waist hole 28 separately. In the present disclosure, the arc-shaped adjustment waist hole 28 may be used to enable the display screen 24 to rotate around the first bolt relative to the bracket 25, so as to adjust the inclination between the display screen 24 and the horizontal plane, thereby adjusting the display screen 24 to an appropriate angle to be convenient for the operator to view the content on the display screen 24.

The telescopic rack further includes barcode readers 29 in a one-to-one correspondence with the storage positions. Each barcode reader 29 is separately located above the corresponding storage position, and is configured to read barcode information on the goods after the goods are placed in the storage position and transmit the barcode information to the display screen 24 for summarization and display. The operator can intuitively know the information about the goods on the telescopic rack by viewing the display screen 24, without viewing them one by one, which is convenient and quick.

A plurality of universal wheels 30 are mounted at the bottom of the rack body 10, so that the rack body 10 can move smoothly. The specific number of the universal wheels 30 may be determined based on actual situations and is not limited herein.

A plurality of feet 31 are mounted at the bottom of the rack body 10. By adjusting the feet 31, the horizontality of the rack body 10 can be adjusted, and the rack body 10 can be placed on the ground smoothly. The specific number of the feet 31 may be determined based on actual situations and is not limited herein.

A ground wire 32 in contact with the ground is further mounted on the bottom of the rack body 10 to conduct the static electricity from the rack body 10 to the ground, so as to prevent the static electricity from damaging the goods placed on the rack body 10.

An embodiment of the present disclosure has been described in detail above, but the content shows merely a preferred embodiment of the present disclosure and cannot be considered as limiting the implementation scope of the present disclosure. All equivalent changes and improvements made according to the scope of the present disclosure shall still fall within the scope of the patent of the present disclosure.

It should be noted that the terms “first”, “second”, and the like used in the present disclosure do not indicate any order, number, or importance, but are merely used to distinguish different components. The descriptions of directions such as “left”, “right”, “left side”, “right side”, “upper”, “lower”, “top”, and “bottom” in the present disclosure are all defined based on the orientation or storage position relationships shown in the accompanying drawings, and are merely used for the convenience of describing the present disclosure and simplifying the description, rather than indicating or implying that the structure must be constructed and operated in a specific orientation, and therefore, should not be construed as limiting the present disclosure. In the description of the present disclosure, unless otherwise explicitly and specifically defined, “plurality of” means two or more.

In the description of the present disclosure, unless otherwise explicitly specified and defined, “mount”, “interconnect”, and “connect” should be understood in their broad sense. For example, they may be fixed connection, detachable connection, or integrated connection; or direct connection, indirect connection via an intermediate, or internal communication between two elements. For those of ordinary skill in the art, the specific meanings of the aforementioned terms in the present disclosure can be understood based on specific situations.

What is claimed is:

1. A telescopic rack, comprising a rack body, material trays, and driving mechanisms, wherein the rack body comprises a shielding layer and a storage layer located below the shielding layer, the storage layer is provided with sliding rails extending in a first direction, the material tray is slidably mounted on the sliding rail through a sliding block, the material tray is provided with at least one storage position for holding goods, and the driving mechanism is configured to drive the material tray to move along the sliding rail so that the storage position moves out of the storage layer.

2. The telescopic rack according to claim 1, wherein the storage layer is provided with a plurality of material trays spaced apart in a second direction, the second direction being perpendicular to the first direction.

3. The telescopic rack according to claim 2, wherein at least one storage position bottom plate is mounted on the material tray, and the storage position is located on the storage position bottom plate and is in a one-to-one correspondence with the storage position bottom plate.

4. The telescopic rack according to claim 3, wherein the storage position comprises a first storage position for holding a wafer cassette and a second storage position for holding a wafer tray carrier; a plurality of first stop blocks defining the first storage position in an enclosing manner and a plurality of second stop blocks defining the second storage position in an enclosing manner are mounted on the storage position bottom plate, the second stop block is disposed on an outer side of the first stop block, and the second stop block at least partially extends above the first stop block.

5. The telescopic rack according to claim 4, wherein the first stop block comprises a first support portion and a first side stop portion disposed at an edge of a top surface of the first support portion, the first side stop portion defines the first storage position on an inner side of the first support portion in an enclosing manner, and the first support portion is configured to support the wafer cassette in the first storage position; the second stop block comprises a second support portion and a second side stop portion disposed at an edge of a top surface of the second support portion, the second side stop portion defines the second storage position on an inner side of the second support portion in an enclosing manner, and the second support portion is configured to support the wafer tray carrier in the second storage position; a height of the second support portion on the storage position bottom plate is not lower than a height of the first side stop portion on the storage position bottom plate.

6. The telescopic rack according to claim 5, further comprising two first in-position sensors and two second in-position sensors, wherein the two first in-position sensors are disposed in the first support portions of two first stop blocks along a diagonal of the first storage position, respectively, and the two second in-position sensors are disposed in the second support portions of two second stop blocks along a diagonal of the second storage position, respectively.

7. The telescopic rack according to claim 4, wherein a presence sensor is separately disposed below each storage position bottom plate, and the presence sensor is configured to detect whether goods are placed on a corresponding storage position bottom plate.

8. The telescopic rack according to claim 1, further comprising a display screen for displaying information about goods on the telescopic rack, wherein the display screen is mounted on the rack body with an adjustable inclination angle.

9. The telescopic rack according to claim 1, further comprising barcode readers in a one-to-one correspondence with the storage positions, wherein the barcode reader is configured to read barcode information on goods.

10. The telescopic rack according to claim 1, wherein a plurality of feet are mounted at a bottom of the rack body;
and/or,
a ground wire in contact with ground is mounted at the bottom of the rack body.
